(19) United States
(12) Patent Application Publication
(10) Pub. No.: US 2025/0056767 A1
(43) Pub. Date: Feb. 13, 2025

(54) DEVICE FOR COOLING AN ELECTRICAL EQUIPMENT ITEM, CORRESPONDING SYSTEM AND AIRCRAFT COMPRISING AT LEAST ONE SUCH SYSTEM

(71) Applicant: Airbus SAS, BLAGNAC (FR)

(72) Inventor: Antoine LOEHRMANN, BLAGNAC (FR)

(21) Appl. No.: 18/794,697

(22) Filed: Aug. 5, 2024

(30) Foreign Application Priority Data
Aug. 9, 2023 (FR) 2308616

(51) Int. Cl. H05K 7/20

(52) U.S. Cl. CPC H05K 7/20409; H05K 7/20327; H05K 7/20381

(57) ABSTRACT

A device for cooling an electrical equipment item including a circulation channel containing a flow of a diphase coolant; a thermally conductive wall configured to separate the channel and the electrical equipment item, at least one fin disposed within the channel and extending from the wall, each fin being configured to be in a position close to the wall when the temperature of the fin is less than a predetermined temperature, and to be in a distant position when the temperature of the fin is greater than or equal to the predetermined temperature. Such a device makes it possible to effectively cool an electrical equipment item without having to decrease the power thereof in the case of very high thermal losses.

### CROSS-REFERENCES TO RELATED APPLICATIONS

This application claims the benefit of French Patent Application Number 2308616 filed on Aug. 9, 2023, the entire disclosure of which is incorporated herein by way of reference.

### FIELD OF THE INVENTION

The present invention relates to a cooling device for electrical and/or electronic equipment items (grouped together under the term “electrical equipment items” hereinafter in the description). The invention relates more particularly to the cooling of such equipment items by the circulation of a diphase coolant. The invention relates also to a cooling system comprising a cooling device and an electrical equipment item, as well as an aircraft comprising at least one such system.

### BACKGROUND OF THE INVENTION

In the context of the electrification of aircraft, the needs for energy have been seen to increase significantly in a few years. Indeed, the electrical systems linked to the flight of aircraft (flight controls, computers, flight computers, etc.) and the electrical systems dedicated to passengers (pressurization systems, ventilation systems, digital entertainment systems, etc.) all generate an increase in the power to be delivered to ensure optimal operation of the aircraft in all conditions.

However, to address these increasing power needs, it is not always possible to increase the size of the electrical equipment items since bulk and weight limitations, in particular, have to be observed.

To try to observe the limitation concerning the bulk of these electrical equipment items, one solution consists in increasing the operating temperature of the power electronics of these equipment items, which does however generate very significant thermal losses. To remedy this, the conventional single-phase coolant system has been replaced by a diphase cooling system 9 illustrated in FIGS. 1a and 1b, also called phase-change cooling system. Thus, the coolant 93 circulating around or over the electrical equipment item 92 will change phase, that is to say, the coolant 93 will change from the liquid state 93a to the gaseous state 93b on contact with the wall 921 of the circuit of the electrical equipment item 92.

One drawback with this solution lies in the fact that, in the event of excessive thermal flux 91 generated by the electrical equipment item 92, in other words in case of excessive thermal flux (called critical thermal flux-CHF), the wall 921 risks becoming dry, as illustrated in FIG. 1b. If the wall 921 is dried, that is to say, if the wall 921 is no longer in contact with the fluid 93a in the liquid state, the temperature of the circuit of the electrical equipment item 92 will only be increased exponentially. The risks of degradation, even of destruction, of the electrical equipment item 92 are therefore very high.

To counter this situation, it is known practice to reduce the power of the electrical equipment item, at least temporarily, to lower the temperature of the circuit. Now, this reduction of power can prove impossible, even dangerous, for example during the take-off phase of the aircraft or during specific maneuvers.

There is, therefore, a need to provide a solution for cooling an electrical equipment item, notably for aircraft, which at least partly remedies the above mentioned drawbacks. Preferably, this solution must be effective, simple to implement and of little bulk.

### SUMMARY OF THE INVENTION

One object of the present invention is to propose a device for cooling an electrical equipment item which is simple to implement and which observes the bulk limitations linked to aircraft in particular.

To this end, a device is proposed for cooling an electrical equipment item, the electrical equipment item comprising a circuit whose temperature increases between a nominal operation of the electrical equipment item in which the circuit delivers a nominal power and a critical operation in which the circuit delivers a critical power greater than the nominal power, the device (1) comprising:
a circulation channel containing a flow of a coolant, the coolant being a diphase fluid having a liquid phase and a gaseous phase,
a thermally conductive wall intended to separate the channel and the circuit and intended to be in contact with the circuit,
at least one fin disposed in the channel and extending from the wall, each fin comprising a proximal end secured to the wall and a distal end opposite the proximal end, each fin being movable between a closed position, in which the distal end is close to the wall, and a distant position, in which the distal end is distant from the wall and at least partly forms an obstacle to the flow of coolant.

The at least one fin is configured to be in a close position when a temperature of the fin is less than a predetermined temperature, and to be in a distant position when the temperature of the fin is greater than or equal to the predetermined temperature.

According to the invention, the predetermined temperature is equal to the phase-change temperature of the coolant.

The cooling device of the invention therefore makes it possible to effectively cool an electrical equipment item without having to reduce the power thereof in the case of very high thermal losses.

According to a particular aspect of the invention, the at least one fin comprises a first surface facing the wall when the at least one fin is in close position, and a second surface opposite the first surface. In the distant position, the at least one fin is inclined with respect to the wall and the flow of coolant circulates towards the second surface of the at least one fin.

According to a particular aspect of the invention, the at least one fin comprises a first part made of metal and a second part made of alloy with shape memory.

According to another particular aspect of the invention, the second part comprises a first portion secured to the wall and a second portion secured to the first portion at an elastically deformable junction, the second portion being movable with respect to the wall between the close position and the distant position.

According to yet another particular aspect of the invention, the first part at least partly covers the second portion.

According to a particular aspect of the invention, the first part made of metal is selected from among: copper, aluminum, gold or Inconel®, and the second part 157 made of alloy with shape memory is selected from among: Nitinol (Nickel-Titanium alloy), Copper-Zinc-Aluminum alloy, Copper-Aluminum-Nickel alloy or Iron-Manganese-Silicon alloy.

According to a particular aspect of the invention, the second portion of the fin has a length configured so that, when the at least one fin is in distant position, at least the distal end of the fin reaches the liquid phase when the wall is separated from the liquid phase by the gaseous phase of the coolant.

According to a particular aspect of the invention, the device comprises a plurality of fins, the fins being disposed on the wall in a row, staggered, or in a combination of these dispositions.

The invention relates also to a cooling system comprising an electrical equipment item and a device as described previously, in which the wall of the device is in contact with the circuit of the electrical equipment item.

Further, the invention relates to an aircraft comprising at least one cooling system as described previously.

### BRIEF DESCRIPTION OF THE DRAWINGS

The features of the invention mentioned above, and others, will become more clearly apparent on reading the following description of an exemplary embodiment, the description being given in relation to the attached drawings, in which:

FIG. 1a schematically illustrates a diphase cooling system according to the prior art, when an electrical equipment item to be cooled is in nominal operation;

FIG. 1b schematically illustrates the system of FIG. 1a, when the electrical equipment item to be cooled operates at full power;

FIG. 2 schematically illustrates a cooling system according to the invention, when an electrical equipment item to be cooled is in nominal operation;

FIG. 3 schematically illustrates the system of FIG. 2, when the electrical equipment item to be cooled operates at full power;

FIG. 4 schematically and in isolation illustrates a cooling device according to the invention, when the electrical equipment item to be cooled operates at full power; and

FIG. 5 illustrates an aircraft comprising a plurality of cooling systems according to the invention.

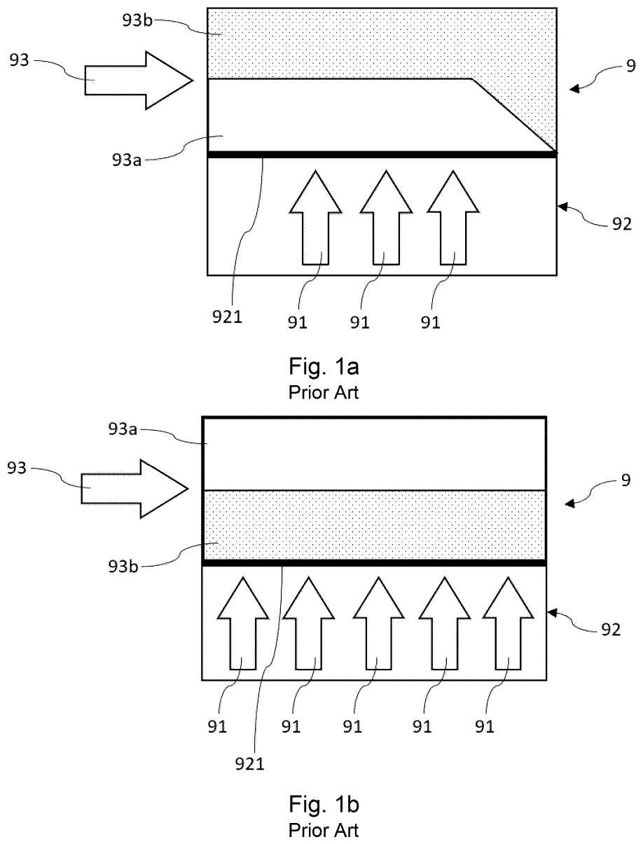

### DETAILED DESCRIPTION OF THE PREFERRED EMBODIMENTS

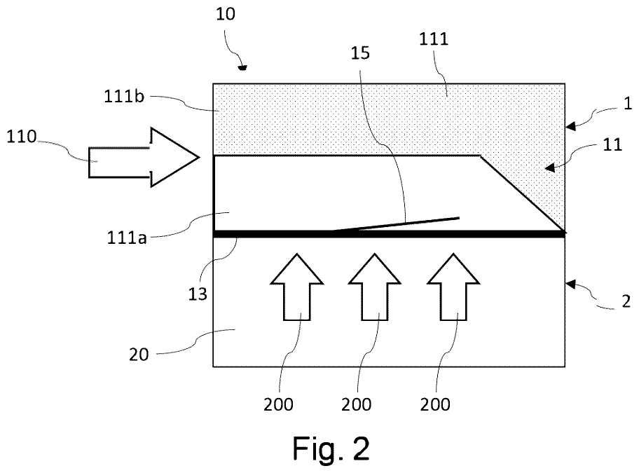

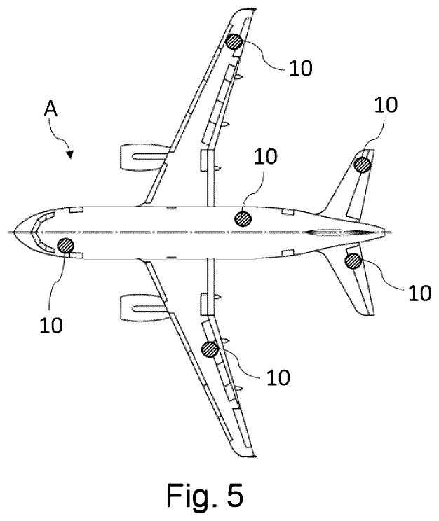

FIGS. 2 to 4 schematically illustrate a cooling device 1 according to the invention. This device 1 is intended to cool an electrical equipment item 2, and preferably an electrical equipment item 2 intended to be embedded in an aircraft A illustrated in FIG. 5.

The electrical equipment item 2 comprises a circuit 20, for example a power electronic circuit, generating a thermal flux 200 when it is operating. Because of this thermal flux 200, the temperature T1 of the circuit 20 is variable as a function of the operation of the circuit 20. Thus, the temperature T1 of the circuit 20 increases when the power delivered by the circuit 20 increases. More specifically, the temperature T1 of the circuit 20 is increasing between a nominal operation of the electrical equipment item 2 in which the circuit 20 delivers a nominal power P1 and a critical operation in which the circuit 20 delivers a critical power P2 greater than the nominal power P1.

For example, the nominal power P1 encompasses a range of power values corresponding to the nominal operation of the electrical equipment item 2. The critical power P2 can be a power value above which the electrical equipment item 2 is considered to be operating at full power.

When the critical power P2 is reached, the temperature T1 of the circuit 20 reaches a critical value. From this critical temperature, the thermal flux 200 is referred to as critical heat flux (referred to by the acronym CHF).

The cooling device 1 of the invention intended to cool such an electrical equipment item 2 comprises a circulation channel 11 containing a flow 110 of coolant 111. According to the invention, the coolant 111 circulating in the channel 11 is a diphase fluid, that is to say, the coolant 111 has two phases, namely a liquid phase 111a and a gaseous phase 111b, within the operating temperature range of the circuit 20.

The device 1 also comprises a wall 13 disposed between the channel 11 and the circuit 20 of the electrical equipment item 2 and separating the channel 11 from the circuit 20. The wall 13 is thermally conductive and is in contact with the circuit 20 so as to promote the thermal exchanges from the circuit 20 to the flow 110, which makes it possible to cool the circuit 20. In a variant, it is possible to envisage the wall 13 being composed of a wall of the electrical equipment item 2.

For example, the wall 13 is manufactured in copper, or in aluminum, or in gold, or in Inconel® (a super-alloy composed primarily of nickel, chrome, iron, magnesium and titanium), or in any other metal that is sufficiently thermally conductive, for example a metal with a thermal conductivity greater than 30 W/mK.

According to the invention, the device 1 comprises at least one elastic fin 15 disposed within the channel 11. In the example illustrated schematically in FIGS. 2 to 4, a single fin 15 is represented and the rest of this description is based on this example. It will easily be understood that the device 1 could implement a plurality of fins 15 and that the following description of the fin 15 could be applied to all the fins 15 when the device 1 comprises a plurality of fins 15.

The fin 15 extends from the wall 13. More specifically, the fin 15 comprises a proximal end 151 secured to the wall 13 and a distal end 153 opposite the proximal end 151. The fin 15 is movable between a close position, in which the distal end 153 is close to the wall 13 (in other words, the fin 15 is lowered and extends overall parallel to the wall 13), and a distant position, in which the distal end 153 is distant from the wall 13 (in other words, the fin 15 is inclined with respect to the wall 13). When the fin 15 is in a distant position, the fin 15 at least partly forms an obstacle to the flow 110 of coolant 111 so as to create disturbances in the flow 110 and increase the thermal exchanges between the circuit 20 and the coolant 111.

More specifically, the fin 15 is configured to be in close position when the temperature T3 of the fin 15 is less than a predetermined temperature Tref and to be in raised position when the temperature T3 of the fin 15 is greater than or equal to the predetermined temperature Tref.

The close position of the fin 15 corresponds to a state in which the electrical equipment item 2 is in nominal operation. Thus, the power P1 delivered by the circuit 20 of the electrical equipment item 2 is then considered to be nominal. The temperature T1 of the circuit 20 is therefore also within the normal operating values. The thermal exchanges between the circuit 20 and the coolant 111 of the flow 110 are therefore sufficient to cool the wall 13. In this situation, the liquid phase 111a of the coolant 111 therefore covers all of the wall 13. In other words, the gaseous phase 111b is not in contact with the wall 13 and the wall 13 is therefore totally wet. The cooling of the electrical equipment item 2 is therefore effective.

When the circuit 20 delivers a higher power which reaches or exceeds the critical power P2, the temperature T1 of the circuit 20 increases. The increasing of the temperature T1 of the circuit 20 will, consequently, increase the temperature T2 of the coolant 111 and therefore the temperature T3 of the fin 15 until the temperature T3 of the fin 15 reaches and possibly exceeds the predetermined temperature Tref.

According to one embodiment, the predetermined temperature Tref corresponds substantially to the phase change temperature of the coolant 111. Thus, when the predetermined temperature Tref is reached, the coolant 111 will change phase such that the volume of the liquid phase 111a will decrease and the volume of the gaseous phase 111b will increase. In addition, because of the capillarity of the coolant 111, the gaseous phase 111b will take the place of the liquid phase 111a and will come to at least partly cover the wall 13. The wall 13 will therefore be dried in places where the liquid phase 111a no longer covers the wall 13 and the temperature T1 of the circuit 20 will increase exponentially. In this situation, the wall 13 is therefore at least partly separated from the liquid phase 111a by the gaseous phase 111b.

In the state of the art, this situation is usually critical and necessitates decreasing the power of the circuit 20 to allow the temperature T1 of the circuit 20 to lower and, consequently, the temperature T2 of the coolant 111 to lower also so that the wall 13 is once again covered by the liquid phase 111a. Now, this need to lower the power delivered by the circuit 20 is not satisfactory.

According to the invention, the fin 15 is configured to be in a distant position when the temperature T3 of the fin 15 reaches or exceeds the predetermined temperature Tref, that is to say, when the temperature T3 of the fin 15 is greater than or equal to the predetermined temperature Tref. Given that the predetermined temperature Tref is equal to the phase-change temperature of the coolant 111, the fin 15 changes from the close position to the distant position overall when the coolant 111 changes phase. Indeed, the temperature T3 of the fin 15 is overall identical to the temperature T2 of the coolant 111 since the fin 15 is bathed in the coolant 111 (that is to say, the fin 15 is in direct contact with the coolant 111). A relatively small deviation, of between five and ten degrees (dependent on the coolant used and the roughness of the fin 15), between the temperature T2 of the coolant 111 and the temperature T3 of the fin 15 can however be observed upon abrupt changes of the temperature T1 of the circuit 20. When there are little or no variations of the temperature T1 of the circuit 20, the temperature T3 of the fin 15 tends to be equal to the temperature T2 of the coolant 111.

In the distant position of the fin 15, the electrical equipment item 2 is considered to be in its critical operation, as described above. Thus, the temperature T2 of the coolant 111 is therefore equal to or greater than the predetermined temperature Tref. Consequently, the liquid phase 111a of the coolant 111 is no longer at least partly in contact with the wall 13, which, because of this, becomes dry. Depending on the temperature T2 of the coolant 111, and therefore on the change of phase of the coolant 111, it may be that the wall 13 is totally dried (that is to say, totally, covered by the gaseous phase 111b) or partially dried (that is to say, a part of the wall 13 is covered by the liquid phase 111a and that another part is covered by the gaseous phase 111b).

The displacement of the fin 15 from the close position to the distant position from the wall 13 makes it possible to create disturbances in the flow 110 of coolant 111 which make it possible to increase the thermal exchanges and therefore ensure the thermal transfer between the wall 13 and the coolant 111. Thus, the circuit 20 can continue to operate at full power, without overheating potentially creating an obstacle to the correct operation of the electrical equipment item 2.

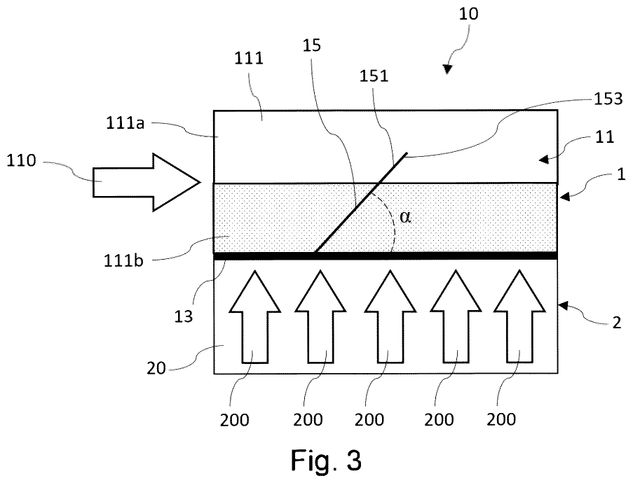

In the embodiment illustrated, the fin 15 comprises a first surface 150a which faces the wall 13 when the fin 15 is in close position. The fin 15 has a second surface 150b which is opposite the first surface 150a, and which is situated on the side of the channel 11 when the fin 15 is in close position. In the distant position, that is to say, when the fin 15 is inclined with respect to the wall 13, or in other words when the fin 15 is straightened, the flow 110 of coolant 111 circulates towards the second surface 150b of the fin 15. In this way, the fin 15 can create disturbances in the flow 110 when the temperature T3 of the fin 15 is greater than or equal to the predetermined temperature Tref. When the temperature T3 of the fin 15 lowers and goes back below the predetermined temperature Tref, then the fin 15 must return to the close position. With this disposition and this inclination of the fin 15, the flow 110 does not oppose the displacement of the fin 15 to the close position. On the contrary, the direction of the flow 110 (represented by the arrow 110 in FIGS. 2 and 3) favors the displacement of the fin 15 from the distant position to the close position.

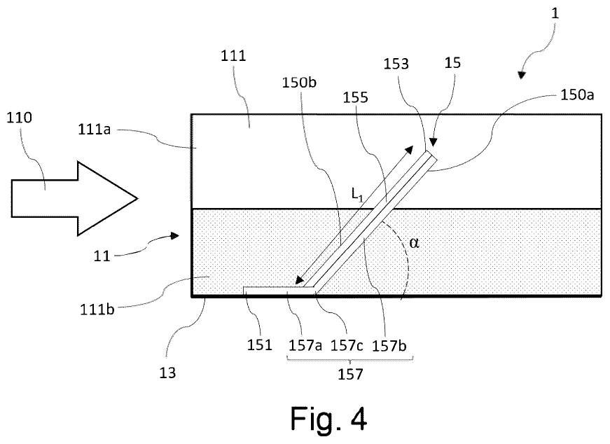

According to a particular aspect illustrated in FIG. 4, the fin 15 is bimetallic and is composed at least of one material with shape memory. More specifically, the fin 15 comprises a first part 155 made of metal and a second part 157 made of alloy with shape memory. The second part 157 made of alloy with shape memory allows an elastic deformation of the fin 15. The deformation of the fin 15 is provoked by the change of the temperature T3 of the fin 15.

More specifically, the second part 157 is configured to deform the fin 15 and switch the fin 15 from the close position to the distant position when the temperature T3 of the fin 15, which is substantially equal to the temperature T2 of the coolant 111, reaches or exceeds the predetermined temperature Tref. As long as the temperature T3 of the fin 15 is greater than or equal to the predetermined temperature Tref, the alloy with shape memory of the second part 157 will keep the fin 15 in distant position. It is therefore the alloy with shape memory of the second part 157 which reacts to the change of temperature. Thus, when the temperature T3 of the fin 15 decreases and goes back below the predetermined temperature Tref, the second part 157 will be deformed once again to revert to its initial form while the metallic first part 155 will assist the return to close position of the fin 15, given that the metallic first part 155 is operated in its elastic range.

The second part 157 made of alloy with shape memory goes through a so-called “learning” phase during which the fin learns to change from the close position to the distant position, and vice versa, at a desired temperature. The first part 155 made of metal makes it possible to assist the displacement from the distant position to the close position.

Such a fin 15 that is elastically deformable as a function of the temperature T3 thereof makes it possible to dispense with the use of a mechanism or an actuator for displacing the fin 15 between the close position and the distant position, and vice versa. The device 1 therefore has a reduced bulk which is optimized and particularly suited for implementation in an aircraft, for example.

Preferably, the second part 157 made of alloy with shape memory comprises a first portion 157a secured to the wall 13 and a second portion 157b that is movable with respect to the wall 13. The first portion 157a, which constitutes a base, is preferably fixed to the wall 13 in a way that ensures a good thermal conduction. For example, the fixing of the first portion 157a to the wall 13 is obtained by brazing, cold soldering, laser welding or any other technique that makes it possible to obtain the same advantages. The type of fixing is notably selected as a function of the material of the wall 13 and of the alloy with shape memory constituting the second part 157 of the fin 15, of the coolant 111 used and of the operating temperature T1 of the circuit 20.

The second part 157 also comprises a junction 157c between the first 157a and second 157b portions. This junction 157c constitutes the point of elastic deformation of the fin 15 and allows the fin 15 to be displaced between the close position and the distant position.

Preferably, the metallic first part 155 at least partly covers the second portion 157b of the second part 157 of the fin 15. Preferably, the first part 155 covers a surface of the second portion 157b of the second part 157 of the fin 15, and more preferably, the second part 157 covers the second surface 150b of the fin 15. As previously, and depending on the material of the wall 13 and the alloy with shape memory constituting the second part 157 of the fin 15, on the coolant 111 used and on the operating temperature T1 of the circuit 20 in particular, the first part 155 is fixed to the second portion 157b of the second part 157 by bonding, cold soldering, laser welding or any other technique that makes it possible to obtain the same advantages. Preferably, the fixing of the first part 155 to the second portion 157b is done at each of the ends of the second portion 157b, that is to say, in proximity to the junction 157c and at the distal end 153.

Preferably, the first part 155 made of metal is selected from among: copper, aluminum, gold, Inconel®, or any other metal that is sufficiently thermally conductive, for example a metal with a thermal conductivity greater than 30 W/mK.

The second part 157 made of alloy with shape memory is selected from among: Nitinol (Nickel-Titanium alloy), or the Copper-Zinc-Aluminum alloy, or the Copper-Aluminum-Nickel alloy, or the Iron-Manganese-Silicon alloy.

Preferably, the second portion 157b of the fin 15 has a length L₁ (illustrated in FIG. 4) configured so that, when the fin 15 is in distant position, at least the distal end 153 of the fin 15 reaches the liquid phase 111b of the coolant when the wall 13 is separated from the liquid phase 111a by the gaseous phase 111b. In other words, during the critical operation of the electrical equipment item 2 and therefore when the wall 13 is dried or partially dried (that is to say, totally or partially covered by the gaseous phase 111b), the length L₁ of the second portion 157b of the fin 15 is sufficient to reach the liquid phase 111a. In this way, the fin 15 will create disturbances in the flow 110 of coolant 111 which will promote the thermal exchanges. More particularly, the fact that the fin 15 can reach the liquid phase 111a when the wall 13 is separated from the liquid phase 111a by the gaseous phase 111b also makes it possible to create disturbances in the liquid phase 111a of the flow 110 to further improve the thermal exchanges. Thus, the temperature T2 of the coolant 111 decreases more rapidly. The same therefore applies for the temperature T1 of the circuit 20.

According to one embodiment, the second portion 157b of the fin 15 has a length less than the length necessary for, when the fin 15 is in distant position, at least the distal end 153 of the fin 15 to reach the liquid phase 111b of the coolant when the wall 13 is separated from the liquid phase 111a by the gaseous phase 111b. In other words, the second portion 157b of the fin 15 does not reach the liquid phase 111b when the wall 13 is dried. The deployment of the fin 15 forces the recirculation of the fluid, which increases the thermal exchanges, reducing the temperature of the fin 15 and of the wall 13, and therefore a rewetting of the wall 13 is possible. According to this configuration, the effectiveness of the cooling is lessened and the rewetting time is extended by comparison to the configuration in which the second portion 157b of the fin 15 has a length that is sufficient to reach the liquid phase 111b.

Preferentially, the predetermined temperature Tref from which the fin 15 changes from the close position to the distant position, and vice versa, is equal to the phase-change temperature of the coolant 111. Because the temperature T3 of the fin is substantially equal to the temperature T2 of the coolant 111, as soon as the coolant 111 heats up too much and begins to change phase, then the fin 15 will be straightened to change from the close position to the distant position. This changing of position of the fin 15 makes it possible to promote the thermal exchanges and avoid having the temperature T2 of the coolant 111 increase excessively, the change of phase taking place and the wall 13 becoming dry. That thus makes it possible to effectively cool the circuit 20 by notably avoiding having the wall 13 become dry. The circuit 20 can thus continue to operate at full power without the fear of overheating being able to damage the latter.

In an embodiment that is not illustrated, it is possible to envisage the device 1 having a plurality of fins 15 in the channel 11 so as to create advantages of disturbances in the flow 110 and therefore further improve the thermal exchanges between the coolant 111 and the circuit 20.

The fins 15 can, for example, be disposed in a line or in columns, or else staggered, on the wall 13. These dispositions make it possible to create disturbances which optimize the thermal exchanges. With these dispositions, it is also possible to anticipate, that is to say, predict, the disturbances which will be created by the fins 15 and therefore the points where the thermal exchanges will take place. It is therefore also possible to dispose fins 15 at specific points in the channel 11 corresponding to points of the circuit 20 that give off the most heat. The fins 15 can thus be placed in the zones of the channel 11 where hot spots have been identified. The density of the fins 15 can be greater, for example two times greater, in these zones of the channel 11 where hot spots have been identified, than in other zones of the channel 11 where no hotspot has been identified. Other dispositions can obviously be envisaged without departing from the principle of the invention.

FIGS. 2 and 3 represent a cooling system 10 according to the invention comprising a device 1 as described previously and an electrical equipment item 2 to be cooled. To allow the cooling of the electrical equipment item 2, the wall 13 of the device 1 is then placed in contact with the electrical equipment item 2, and preferably with the circuit 20 which generates the thermal flux 200, to allow the thermal exchanges between the flow 110 of coolant 111 and the thermal flux generated by the circuit 20.

FIG. 5 represents an aircraft A comprising at least one cooling system 10 as described above. In this example, several systems 10 are implemented in the aircraft A. The use of such systems 10 in an aircraft advantageously makes it possible to use the electrical equipment item 2 in operation at full power over the desired periods, without having the need to decrease the power owing to the untimely heating-up of the electrical equipment item 2. In this way, the use of the electrical equipment item 2 is optimized and corresponds notably to the limitations of operation and of bulk encountered in an aircraft.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A device for cooling an electrical equipment item, the electrical equipment item comprising a circuit whose temperature is increasing between a nominal operation of the electrical equipment item in which the circuit delivers a nominal power and a critical operation in which the circuit delivers a critical power greater than the nominal power, comprising:
a circulation channel containing a flow of a coolant, the coolant being a diphase fluid having a liquid phase and a gaseous phase,
a thermally conductive wall configured to separate the channel and the circuit and configured to be in contact with the circuit,
at least one fin disposed within the channel and extending from the wall, each fin comprising a proximal end secured to the wall and a distal end opposite the proximal end, each fin being movable between a close position, in which the distal end is close to the wall, and a distant position, in which the distal end is distant from the wall and at least partly forms an obstacle to the flow of the coolant;
wherein said at least one fin is configured to be in close position when a temperature of the fin is less than a predetermined temperature, and to be in distant position when said temperature of the fin is greater than or equal to said predetermined temperature; and
wherein said predetermined temperature is equal to a phase-change temperature of said coolant.

2. The cooling device according to claim 1,
wherein said at least one fin comprises a first surface facing said wall when said at least one fin is in close position, and a second surface opposite said first surface,
wherein, in the distant position, said at least one fin is inclined with respect to said wall and wherein said flow of coolant circulates towards said second surface of said at least one fin.

3. The cooling device according to claim 1, wherein said at least one fin comprises a first part made of metal and a second part made of alloy with shape memory.

4. The cooling device according to claim 3, wherein said second part comprises a first portion secured to said wall and a second portion secured to said first portion at an elastically deformable junction, said second portion being movable with respect to said wall between the close position and the distant position.

5. The cooling device according to claim 4, wherein said first part at least partly covers said second portion.

6. The cooling device according to claim 3,
wherein said first part made of metal is selected from among: copper, or aluminum, or gold, or Inconel®, and
wherein said second part made of alloy with shape memory is selected from among: Nitinol, or a Copper-Zinc-Aluminum alloy, or a Copper-Aluminum-Nickel alloy, or an Iron-Manganese-Silicon alloy.

7. The cooling device according to claim 4, wherein said second portion has a length configured so that, when said at least one fin is in distant position, at least the distal end of said fin reaches the liquid phase when said wall is separated from said liquid phase by the gaseous phase of said coolant.

8. The cooling device according to claim 1, further comprising a plurality of fins, said fins being disposed on said wall in a line, staggered, or a combination of these dispositions.

9. A cooling system comprising an electrical equipment item and a cooling device according to claim 1, wherein said wall of said device is in contact with said circuit of said electrical equipment item.

10. An aircraft comprising at least one cooling system according to claim 9.
